(19) United States
(12) Patent Application Publication
(10) Pub. No.: US 2003/0178655 A1
(43) Pub. Date: Sep. 25, 2003

(54) Dual sided power amplifier

(75) Inventor: Thomas A. Winslow, Salem, VA (US)

Correspondence Address: McDERMOTT, WILL & EMERY, 600 13th Street, N.W., Washington, DC, 20005-3096, US

(73) Assignee: Tyco Electronics Logistics AG

(21) Appl. No.: 10/101,945

(22) Filed: Mar. 21, 2002

(51) Int. Cl. H01L 29/80

(52) U.S. Cl. 257/280

(57) ABSTRACT

The invention features an improved semiconductor device comprising both active and passive devices and a method of manufacturing such semiconductor devices. A method in accord with the invention includes performing front side processing on a front side of the substrate to form an active semiconductor device on the front side of the substrate and performing back side processing on the back side of the substrate. The back side processing includes forming a via through the back side of the substrate to an electrically conductive layer formed on the front side of the substrate and forming a conductive layer in the via to form an electrically conductive path from the back side of the substrate to the electrically conductive layer formed on the front side of the substrate. The backside processing also includes forming a passive semiconductor device on the back side of the substrate and forming an electrical connection between the passive semiconductor device, the via, and the electrically conductive layer formed on the front side of the substrate.

### FIELD OF INVENTION

The present invention generally relates to semiconductor devices and methods of manufacturing the same. More particularly, the invention relates to semiconductor devices comprising both active and passive devices, including field effect transistors (FETs) having metal-semiconductor (MES) or metal-insulator-semiconductor (MIS) gates, and methods of manufacturing the same. More particularly, the invention relates to semiconductor devices having active devices on one side of a substrate and passive devices on another side of the substrate, to form a dual sided semiconductor device such as, but not limited, to an amplifier.

### BACKGROUND OF THE INVENTION

GaAs MESFETs are well known devices for providing amplification at microwave frequencies, high speed digital switching, and various other functions. The use of microwave frequencies in satellite and wireless communications has been increasing rapidly, driving improvements in GaAs transistors. As the power output of MESFETs improves, and newer single MESFETs replace a plurality of older MESFETs, the size and cost of amplifier modules can be reduced. Accordingly, there has been a tremendous effort to improve the performance of these GaAs devices to achieve such miniaturization of MESFETs and devices incorporating the same.

Conventional MESFETs employ a metal gate electrode in direct contact with a GaAs substrate to form what is known as a Schottky barrier. A voltage applied to the gate electrode influences a current carrying region beneath the gate, thereby controlling the flow of current between the drain and source electrodes, thereby providing amplification or switching.

FIG. 1 illustrates a cross-sectional view of a conventional n-channel MESFET 10. An n⁺ source region 14, n⁺ drain region 12, and an n-doped channel region 15 are formed within a GaAs substrate 11. Gate, source and drain electrodes s, g, and d, respectively, are then formed on the respective doped regions, with the gate electrode g typically offset toward the source electrode s to reduce parasitic source resistance. When a voltage is applied between the gate and source electrodes g and s, it controls a surface depletion region 16 formed within the channel 15, through which current flows from drain to source upon the application of a bias voltage between the drain and source elements.

For the GaAs industry in general, variability in FET performance within a circuit, across a wafer, and from wafer to wafer has been the a significant factor responsible for yield loss and the high cost of Monolithic Microwave Integrated Circuits (MMICs).

One conventional approach to manufacturing GaAs MESFETs utilized recessed gates, such as shown in U.S. Pat. No. 5,675,159 issued to Oku et al. or U.S. Pat. No., 6,180,440 issued to Koganei. In this approach, a gate was formed at the bottom of an etched trough or recess in the GaAs channel region. However, the resulting structure is more difficult to manufacture than a planar device. One fabrication method, generally disclosed in U.S. Pat. No. 6,236,070 issued to Griffin et al. and assigned to the present assignee, incorporated herein by reference, improves upon the conventional recessed gate approach by utilizing a self-aligned gate FET fabrication approach to improve reproducibility and yield, necessary objectives for MMIC fabrication. This process, referred to as the Multifunction Self-Aligned Gate (MSAG) process, is able to fabricate small-signal (low-noise) and power MMICs as well as digital GaAs ICs on a single chip without compromising performance. This process takes advantage of well-proven silicon large scale integration (LSI) manufacturing techniques including photoresist planarization and plasma processing. Other aspects of this process are found in U.S. Pat. No. 6,313,512 issued to Schmitz et al., U.S. Pat. No. 4,956,308 issued to Griffin et al., and U.S. Pat. No. 4,847,212 issued to Balzan et al., each assigned to the present assignee and each incorporated herein by reference.

The MSAG process achieves superior uniformity in two ways. First, eliminating the gate recess allows precise control of active channel thickness and doping concentration. Second, self-aligned gate processing techniques lessen parasitic gate-source resistance. The results of a manufacturing run of 2-18 Ghz small signal FETs show standard deviation of I_{dss} and gain across 500,000 devices was 5.7 and 4.7 percent, respectively. Similarly, the standard deviation of Idss and P_{1dB} for a run of 20,000 1.5 W C-band power FETs was 2.1 and 5.3 percent. The excellent performance up through 18 GHz is achieved with nominal 0.8 μm lithography, further enhancing circuit manufacturing.

Key features of the MSAG FET include: 1) n⁺ implant self-aligned to the source edge of the gate for reproducible low gate-source resistance; 2) n⁺ implant displaced from the drain side of the gate for high breakdown voltage and high output resistance (microwave FETs only); 3) channel thickness precisely defined via ion implantation alone (no gate recess); 4) low gate resistance with gate metal cap; and 5) completely passivated GaAs surface for long-term stability and reliability. FIG. 2 shows a basic circuit arrangement for which MESFET 10 provides amplification of an RF input signal. The circuit 20 amplifies the RF input signal applied to input terminal 18 to provide an amplified RF output across a load resistor R_{L}. Inductors L1 and L2 act as AC chokes to bring DC bias voltages V_{gg} and V_{dd} to the respective gate and drain terminals of device 10. Capacitors C₁ and C₂ function as DC blocks, while input and output matching structures 17 and 19 are employed to transform the relatively high input and output system impedances to generally lower device impedances, to optimize the performance of the MESFET 10.

FIGS. 3(a) and 3(b) illustrate conventional integrated circuit power amplifiers. FIG. 3(a) shows an integrated circuit power amplifier 50 laid out using a prior art industry standard approach for the layout of the FETs 60. FIG. 3(b) shows a 3.6 V, 3.5 W radio frequency power amplifier 50′ laid out for use in Global System for Mobile (GSM) communication handsets, in accord with the invention disclosed in U.S. Pat. No. 6,313,512 issued to Schmitz et al., incorporated herein by reference, showing a layout of the FETs 60′. Inductive elements 70, 70′ and bond pads 80, 80′ are also shown.

Chip packaging plays another important role in miniaturization and cost-minimization of MESFETs and devices incorporating the same.

One conventional chip layout/assembly technique is based on flip-chip technology. This technology uses unthinned silicon or GaAs wafers. All active elements and matching/bypass elements and ground are fabricated on one side of a wafer (which will then be diced into individual chips for assembly). Wafers are typically bumped using either a gold stud bump process or a solder plating process. Signal and ground connections are made from the flipped chip to a supporting chip carrier through the conductive bumps. Chips are flipped over and placed face down on a carrier where the exposed interconnects are integrated with the chip carrier or package by means of electrical and mechanical connections to complementary lands on the chip carrier. Such electrical and mechanical connection is realized by, for example, conductive reflowable balls or under-bump metallization (UBM) including solder, gold, or polymer bumps, or combinations thereof, such as a Cr adhesive layer, a Cu solderable layer formed thereover, and an Au flash layer provided to prevent oxidation of the Cu solderable layer. One or more reflow steps are performed to establish the electrical and physical connections between the bonding pads/exposed interconnects on the chip and the respective bonding pads/interconnects on the carrier substrate.

A second conventional chip layout/assembly technique, wire bonding, is typically the most commonly employed. Currently, most commercial IC's are packaged using standard wire bonding techniques, such as depicted in FIG. 4. The chips are typically thinned to 3, 4, or 5 mil. during backside processing. Following thinning, vias are formed using conventional photolithographic and etching techniques to selectively provide openings through the backside of the chip to selected first layer metallizations. Following via formation, the backside of the chip is plating (e.g., Au, Au-alloy plating) to fill the vias and effect ground connections to the active side of the chip. Signal and bias connections are made through wire bonds 92 from the (face-up) chip 90 to its carrier 94. The backside of the chip is then epoxied or soldered to a carrier or leadframe. Matching and bypass components are placed on the top side of the chip.

However, both conventional chip assembly techniques, as described above, only utilize one side of the wafer for ground or matching components, and therefore include the following shortcomings.

Flip chip assembly processes can be superior (electrically and thermally) to standard face-up chip wire bond chip assembly processes. First, flip-chip assembling does not require wafer thinning (requiring no backside wafer processing). Second, since the chip is flipped, heat can be pulled directly out of the active devices (on the wafer surface) to the supporting carrier/module. This makes flip-chip designs thermally superior to the predominant face-up wirebond based chip designs. However, flip-chip applications demand very precise chip placement and therefore require expensive processing equipment/assemblers that can handle bare die. Although flip-chip processing avoids the need for backside wafer processing, it demands extra processing steps to perform the wafer bumping. Furthermore, chip carriers/modules to support flip-chip designs can be more costly than other carrier/modules.

Accordingly, the predominant chip design/assembly technique for low cost Radio Frequency Integrated Circuit (RFIC) applications chip design/assembly technique utilizes thinned chips that are wirebonded to a supporting carrier/module. Bond pads necessary for signal and bias connections are placed along the outer edge of the chip taking up valuable semiconductor area, which increases the cost of a given chip.

Both face-up and flip-chips only utilize one side of the chip to place RF matching, bypassing elements and signal/bias connections.

In view of the ever-present demands for miniaturization and cost reduction, further compaction of semiconductor devices, such as but not limited to GaAs integrated circuit power amplifiers, is needed. It is an object of the present invention to provide a method realizing such miniaturization and cost reduction and a device achievable thereby.

### SUMMARY OF THE INVENTION

It is an object of this invention to provide a semiconductor device, and method of manufacturing thereof, that overcomes the previous limitations by utilizing both sides of the chip for placing RF matching and bypassing elements.

In one aspect, the invention features a method of manufacturing a semiconductor device, comprising the steps of performing front side processing on a front side of the substrate to form an active semiconductor device on the front side of the substrate and performing back side processing on the back side of the substrate, wherein such back side processing includes the steps of: forming a via through the back side of the substrate to an electrically conductive layer formed on the front side of the substrate; forming a conductive layer in said via to form an electrically conductive path from the back side of the substrate to the electrically conductive layer formed on the front side of the substrate; forming a passive semiconductor device on the back side of the substrate; and forming an electrical connection between the passive semiconductor device, the via, and the electrically conductive layer formed on the front side of the substrate.

In another aspect of the invention, a method of manufacturing a power amplifier in accord with the invention comprises the steps of: forming an active semiconductor device comprising a field effect transistor on one side of a substrate; forming a via through the substrate; filling the via with an electrically conductive material; forming a passive semiconductor device comprising at least one of an inductor and a bond pad on another side of the substrate opposing said one side; and electrically connecting the passive semiconductor device to the active semiconductor device through the via.

Yet another aspect of the invention includes an integrated circuit comprising, in combination: a substrate having a front side and a back side; an active device disposed on the front side of the substrate; a passive device disposed on the front side of the substrate; a via bearing a conductive material extending from the back side of the substrate to the front side of the substrate; and electrical connectors connecting a respective one of the active device and passive device to the via conductive material to form an electrical connection between the active device on the front side of the substrate and the passive device on the back side of the substrate.

As described in further detail below, the present invention provides significant advantages over the prior art. For example, the active side of the wafer or chip comprising FETs is placed face down and epoxied/soldered directly to a thermal heat sink. Since the FET source is being directly soldered/epoxied to electrical and thermal ground (no wirebonds from the FET source to ground), RF performance is enhanced by decreasing source inductance and decreasing the thermal resistance from the FET junction to ambient. Also, since only ground regions on the flipped front side of the chip are exposed and attached, this flip chip method still does not require high precision pick and place equipment.

Further, inductors and bond pads on the backside (face up) of the chip can be placed directly above FETs and caps on the active (backside) layer which are soldered/epoxied directly to ground. Utilizing both sides of a chip reduces chip size, which can lower the overall cost of a given RFIC, even considering the increased number of processing steps necessary to make use of the backside of the chip.

Still further, since inductors on the backside (top layer) are not fabricated with a low current handling lift-off metal, or a first level metal, the inductors can be used to provide high Q, high current handling matching elements, and efficient RF chokes.

Still further, by epoxying/soldering the active layer and matching components face down on a carrier/module, design techniques and process technology protection is achieved. The chip would be destroyed if an attempt to remove it from it carrier/module were made for the purpose of reverse engineering.

The chip design/layout is pick/place compatible with current high volume manufacturing techniques and does not require the accurate pick and place capability necessary for flip-chip applications. This chip design/layout technique provides the same thermal and electrical grounding improvement as is achieved in flip-chip designs.

Additional advantages of the present invention will become apparent to those skilled in the art from the following detailed description of exemplary embodiments of the present invention. The invention itself, together with further objects and advantages, can be better understood by reference to the following detailed description and the accompanying drawings.

### BRIEF DESCRIPTION OF THE DRAWINGS

The accompanying drawings, which are incorporated in and form a part of the specification, illustrate embodiments of the present invention and, together with the description, serve to explain the principles of the invention, but are not intended to be limiting thereto.

In the drawings:

FIG. 1 illustrates a cross-sectional view of a conventional n-channel MESFET.

FIG. 2 shows a basic circuit arrangement for an MESFET amplifier.

FIGS. 3(a) and 3(b) illustrate conventional integrated circuit power amplifier topology.

FIG. 4 is a perspective view of a conventional IC wire bond package.

FIG. 5 depicts a cross section of a conventional MSAG FET.

FIGS. 6(a)-6(n) depict process flow steps in accord with the method of the invention.

FIG. 7(a) shows a perspective view of an IC formed in accord with process depicted in FIGS. 6(a)-6(m).

FIG. 7(b) shows a side view of a final IC package assembly step in accord with the invention.

FIGS. 8(a)-8(b) depict a top view and a bottom view of an IC formed in accord with the method of the invention.

FIG. 9 shows an alternative embodiment of a semiconductor device in accord with the invention.

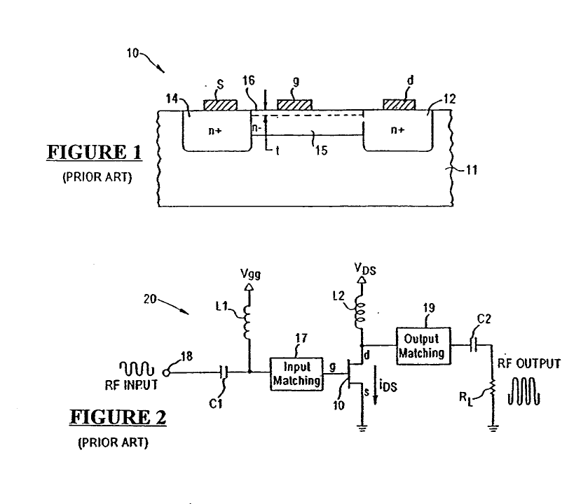

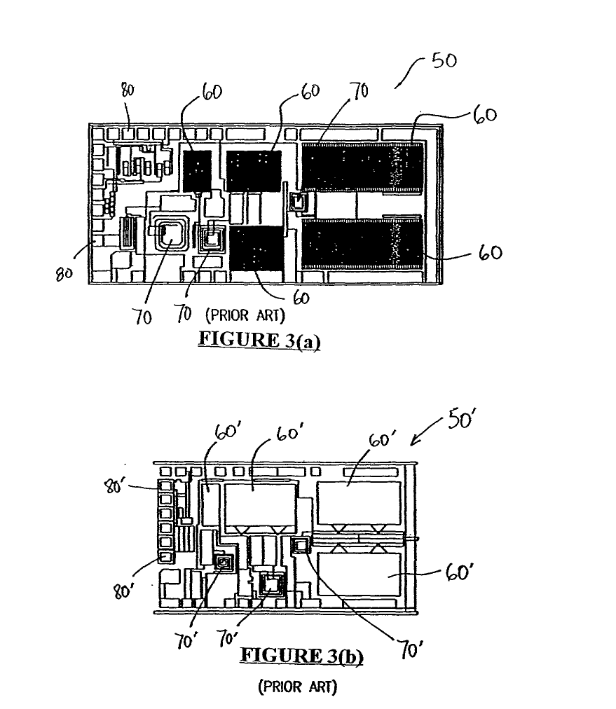

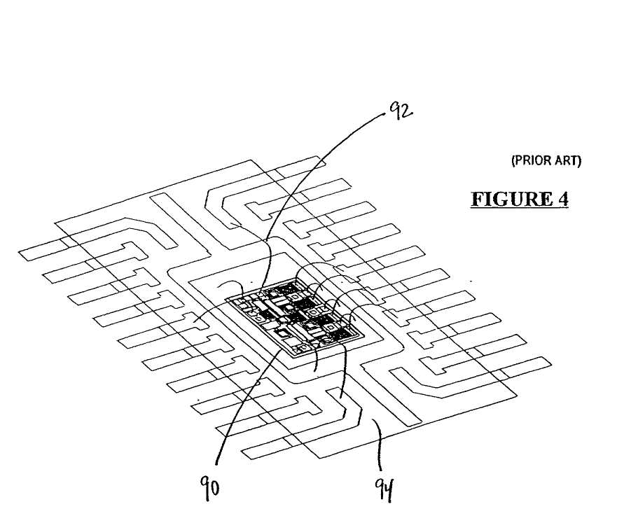

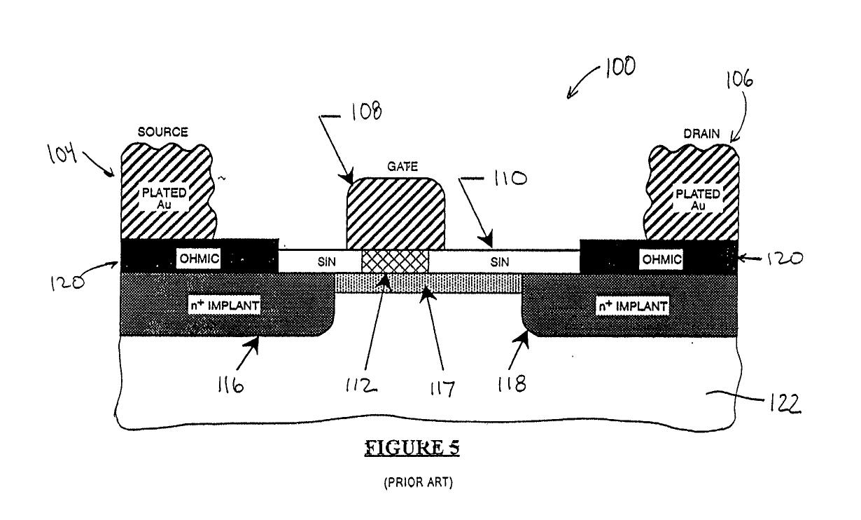

### DETAILED DESCRIPTION OF THE INVENTION

In the following description, for the purposes of explanation, numerous specific details are set forth in order to provide a more thorough understanding of the present invention. It will be apparent, however, to one skilled in the art that the present invention may be practiced without these specific details.

Specifically, the following detailed description of the dual sided circuit of the present invention relates to both the circuit itself as well as a method of forming the circuit. It is noted that in an effort to facilitate the understanding of the present invention, the following description details how the circuit can be utilized in today's state-of-the-art electronic devices. However, the present invention is not limited to use in FETs or amplifiers. Indeed, the invention can be used in a multitude of different types of designs and processes that include any type of semiconductor device, as the invention broadly relates to improvements in semiconductor packaging which are applicable in many spheres of IC design and manufacture.

Miniaturization of a semiconductor in accord with the invention is achieved in part by utilizing the current state of the art FET and device fabrication techniques to form active areas and devices producing the greatest benefit and utilizing the least substrate real estate. The exact fabrication techniques discussed herein are not themselves critical to the invention, but may be advantageously utilized in combination with the invention to achieve further advances in miniaturization and cost minimization. For this reason, an exemplary FET fabrication process is described herein as a precursor to the description of the inventive process.

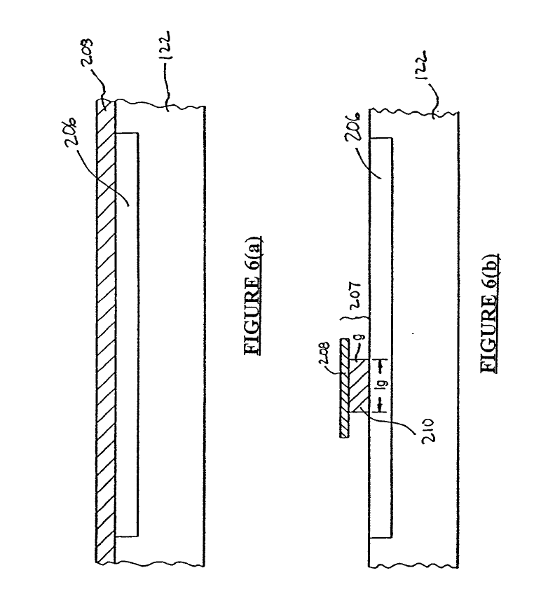

A MSAG FET is depicted in FIG. 5. As shown therein, MSAG FET 100 is formed on a substrate 122, comprising GaAs or other suitable substrate material. The FET 100 comprises source 104 and drain metallizations 106 formed on ohmic contacts 120. Metal cap 108, advantageously comprising gold, is formed on refractory metal gate 112 to, among other things, lower the gate resistance. Refractory metal gate 112, in the embodiment shown, is a 0.4 μm gate formed using 1.0 μm photolithographic techniques and a refractory metal selected to withstand processing steps, such as an 800° C. anneal. N⁺ source region 116 and n⁺ drain region 118 are separated by a channel region 117 formed therebetween. N⁺ region 116 is separated from the gate to increase output resistance and increase breakdown voltage, whereas n⁺ region 118 is precisely and reproducibly self-aligned to the gate to lower source resistance. Passivation layer 110, typically but not exclusively silicon nitride (SiN), is formed over the channel region or active layer implant 114 and serves to passivate the GaAs as well as to support the metal cap 108. The source 104, drain 106, and gate 112 metallizations are termed first level plating, and advantageously comprise gold plating. A passivation layer 130, such as SiN, is formed over the wafer and metallizations to protect the metallizations. Openings are then etched or formed into passivation layer 130 to expose the bond pads, such as source metallization 104.

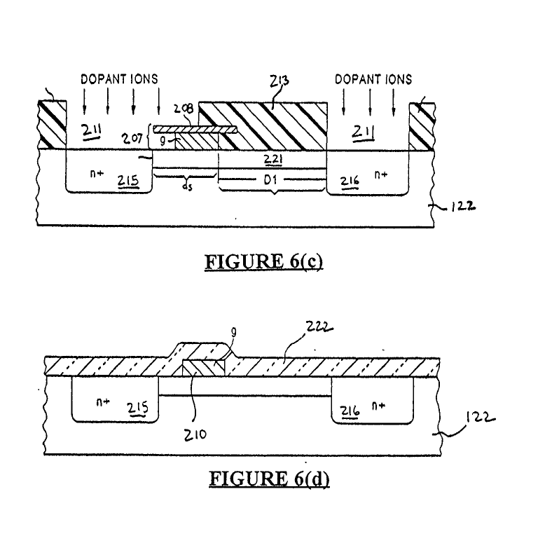

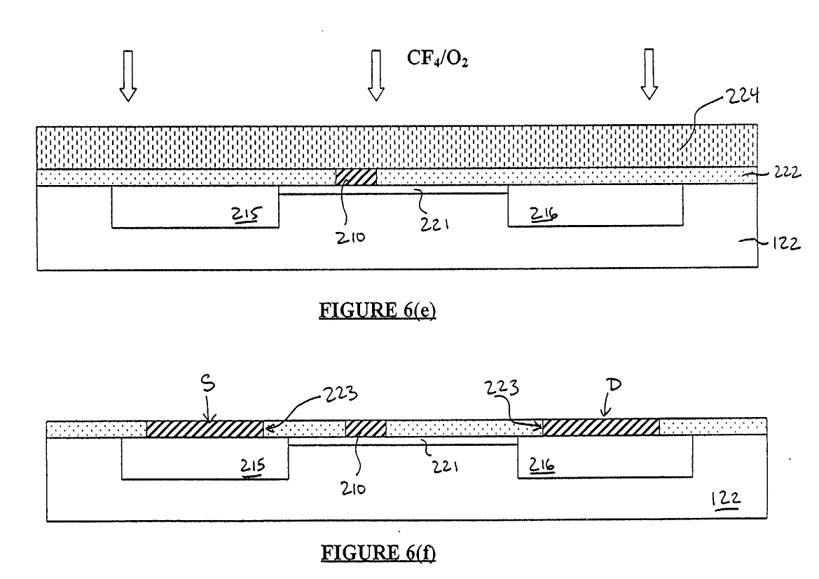

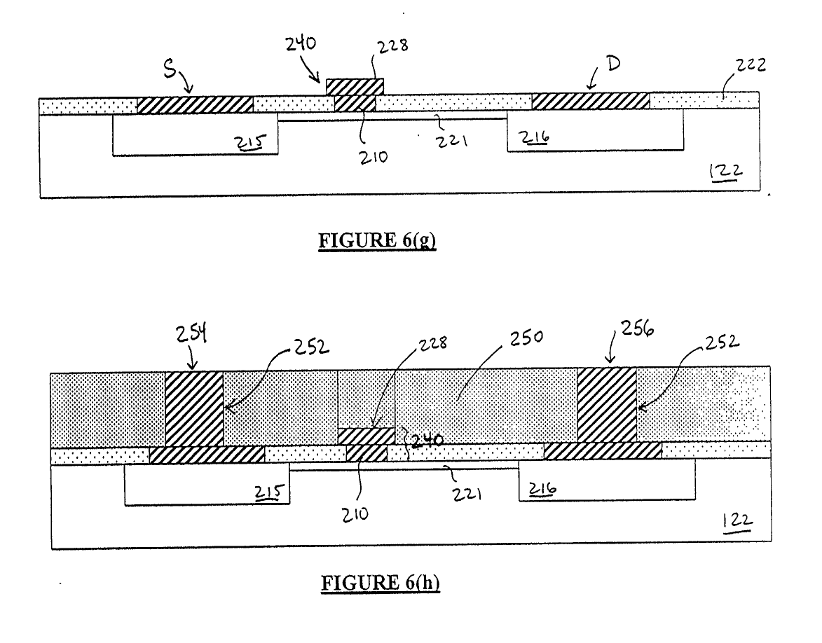

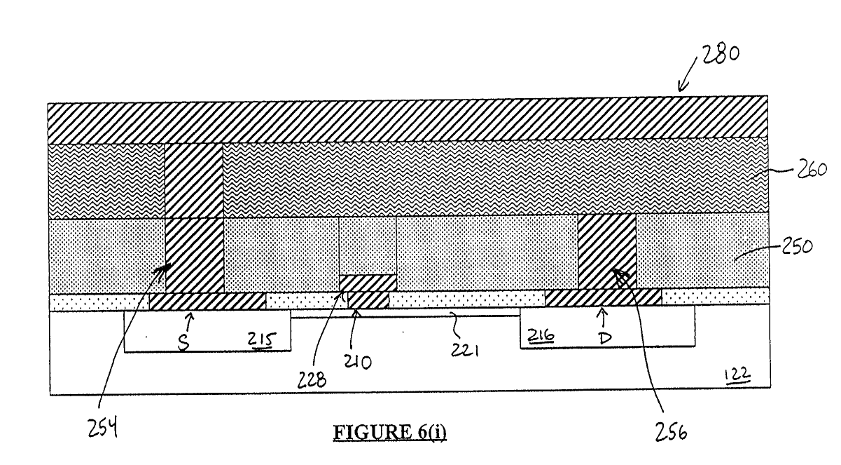

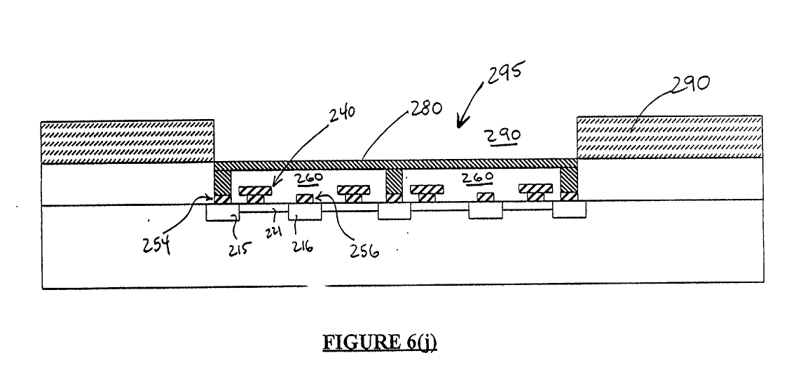

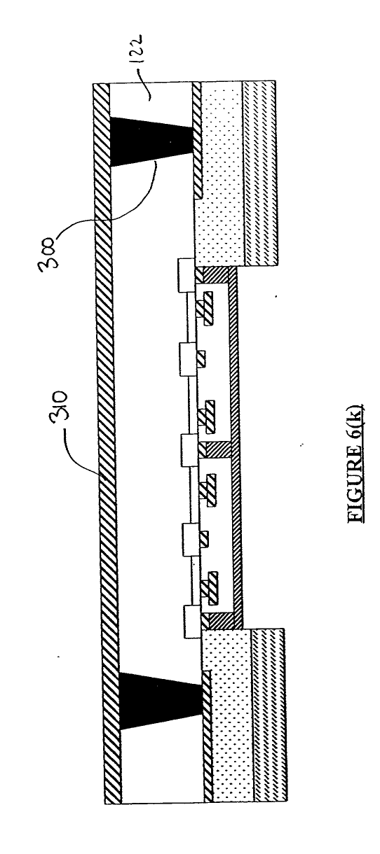

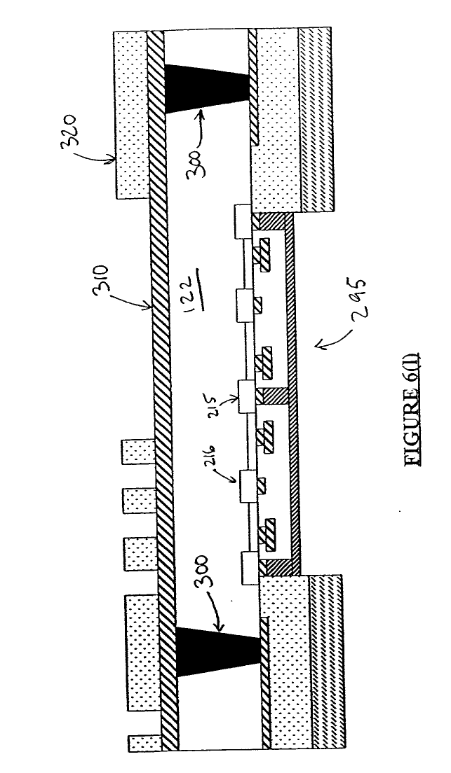

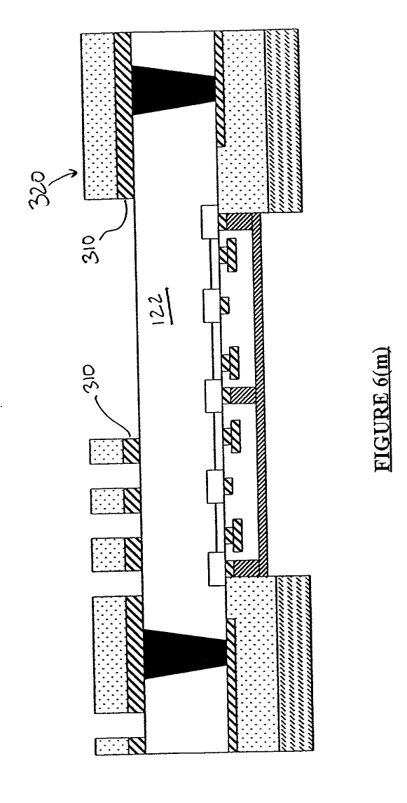

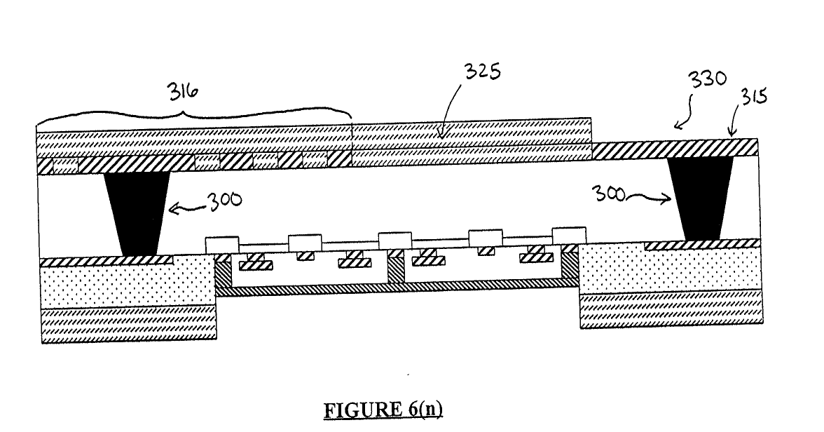

An exemplary process for manufacturing a MSAG FET depicted in FIG. 5 is illustrated in FIGS. 6(a) through 6(m). Prior to the below processing steps, the substrate 122 is initially cleaned in suitable solvents and etched to remove a portion of the substrate which may have been damaged or rendered unsuitable. Techniques for preparing substrates are well known.

After initial preparation of substrate 122, an active channel area is formed for the FET in accord with conventional techniques, as represented in FIG. 6(a). The first step of this planar process includes selective ion implantation into an undoped substrate 122 of GaAs, silicon, Indium-phosphide, Indium Gallium Arsenide (InGaAs), Aluminum Gallium Arsenide (AlGaAs), or any other convention substrate material, including a liquid encapsulated Czochralski (LEC) substrate and other III-V semiconductor substrates. A passivation layer 204, such as plasma enhanced chemical vapor deposition (PECVD) silicon oxynitride (SiON), is then formed on the substrate to passivate substrate 122. Passivation layer 204 is typically a thin layer, such as 80-90 nm. A silicon (Si) implant (n-type) is then performed at about 90 Kev through the SiON passivation layer 204, followed by a Mg⁺ (p-type) co-implant to form the FET active layer 203. The Mg⁺ co-implant sharpens the doping profile by reducing the tail of the n-type implant, providing improved device transconductance and pinch-off characteristics. SiON passivation layer 204 is then removed.

After removal of SiON passivation layer 204, a first level or layer metallization (not shown), such as a film of refractory metal or titanium tungsten, titanium tungsten nitride (TiWN), tungsten nitride, or tungsten silicide, or any other metal or alloy having sufficient thermal stability to withstand high temperature processing steps (e.g., 750° C. to 1000° C. or higher) without degradation of its Schottky barrier properties, is deposited by conventional means, such as reactive sputtering in an atmosphere of 25% N₂ in Ar.

A metal etch mask 208 having a thickness of about 150 nm is formed by evaporation and liftoff. Preferred etch mask 208 materials include nickel (Ni), aluminum (Al), and gold (Au), but is commonly Ni. Excess metallization from the first level metallization is then removed by plasma or reactive-ion etching (RIE), so as to leave only gate metal 210 under the metal etch mask 208. The illustrated gate electrode 210 has a length Lg of about 0.4 microns.

The RIE is preferably performed in three steps to produce a reproducible self-limiting undercut (1) a brief argon etch under low pressure and high power (20 mTorr, 0.4 W/cm²); (2) a CF₄ or other reactive fluorine-species etch at medium pressure and power of sufficient length to remove the refractory metal from the unmasked regions of the wafer (40 mTorr, 0.2 W/cm²); and (3) a CF₄/O₂He (40:10:50 partial pressures) etch at high pressure and low power (200 mTorr, 0.08 W/cm²). It is preferred not to expose the wafer to atmosphere between each step. The illustrated gate electrode 210 has a length L_{g} of about 0.4 microns.

The first step, above, cleans the metal surface, removing any undesirable metal, contaminants, or oxides present on the surface of the first metallization layer (e.g., TiWN). This step produces a clean, consistent metal surface for subsequent RIE steps. The second step produces aniostropic profiles in the etched first metallization layer with no measurable undercut, simply reproducing the etch mask dimensions in the underlying metallization layer. The etching time in this step is forgiving, as a slight undercut of the mask is not of concern. The third step is a self-limiting etch which undercuts the etch mask by a reproducible amount and the parameters of the etch may be adjusted to tailor the undercut dimensions for a particular application. For the above-noted exemplary etch conditions, wherein the refractory layer is about 2000 Å thick and the etch mask is about 1.4 μm wide, the self-limiting undercut of the etch mask is about 0.4 μm on each side of the gate. The gate length may be varied by varying the etch mask dimension. The undercut may be varied slightly by varying the etch timing or etch recipe. This process is used to pattern the illustrated TiWN layer into ‘T-gate’ structure 207, comprising etch mask 208 and the TiWN gate electrode 210. Optical end-point detection may be used, in a manner known to those skilled in the art, to control the 1 μm Ni etch mask 208 undercut to produce a 0.4 μm Schottky contact.

As seen in FIG. 6(c), after defining the ‘T-gate’ structure 207, the wafer is coated with a photoresist 212 and patterned to form openings 211 on either side of the ‘T-gate’ structure 207 in preparation for the n⁺ implant. The ‘T-gate’ 207, and optionally in conjunction with a photoresist stripe 213, serves to mask the channel region during n⁺ implant. Suitable dopant ions are then implanted at an energy of about 120 Kev into the substrate 122 in the region of the openings 211. A preferred dopant ion is silicon, although any n-type dopant ion may be used. As depicted in FIG. 6(c), the n⁺ region adjacent the source side 215 and the n⁺ region adjacent the drain side 214, are heavily doped (e.g., greater than about 1.0×10¹⁸ ions/cm³) by means of the dopant ions and form regions of high conductivity relative to the channel 221 (e.g., greater than about 1-4×10¹⁷ ions/cm³).

Openings 211 may be asymmetrically disposed with respect to the gate, such that the gate is disposed closer to the n⁺ region on its source side than the n⁺ region on the drain side, or may be symmetrically disposed, depending on the desired properties. For example, increased separation distance of n⁺ from the drain side of the gate electrode 210 greatly increases the FET output resistance and breakdown voltage while the distance resulting in the self-alignment of n⁺ to the ‘T-gate’ 207 on the source side 215 results in extremely low, reproducible source resistance. FETs providing small signal or power amplification may utilize such an asymmetrically placed stripe 213. For example, the separation distance D₁ might be approximately 1.5 μm to provide an “extended” drain spacing region ds. The use of the extended drain region ds improves the breakdown voltage of the device. On the other hand, microwave switching FETs may typically employ a symmetrical resist stripe placement to achieve symmetrical device characteristics with high breakdown voltages. Digital FETs on the other hand, may typically omit the resist stripe entirely to provide symmetrical devices with the lowest possible parasitic resistances. To reduce parasitic resistances even further, digital FETs may also include an n⁺ implant performed after the Ni gate etch mask has been removed. Optionally, the etch mask 208 may be left in place to reduce the overall electrical resistance of the gate electrode, provided the resulting structure is thermally stable during anneal.

After removal of the etch mask 208 (e.g., a Ni etch mask), such as by chemical removal, and removal of the remaining photoresist 213, the substrate 122, particularly the gate electrode structure 210, is capped with a suitable dielectric layer 222 and annealed to activate the implants, as represented in FIG. 6(d). Dielectric layer 222 is preferably silicon oxynitride (SiON), although silicon dioxide and silicon nitride are equally suitable. A suitable dielectric layer 222 for this purpose could include a 100-200 nanometers thick layer of SiON deposited by PECVD. Additionally, the dielectric layer 222 may be selected to permit the dielectric material to be used not only as anneal cap, but also as an implant mask, thereby permitting an additional, optional self-aligned implant. The thickness of the dielectric layer 222 and the selected implant energy would have to varied, in a manner known to those skilled in the art, to prevent masking of the ion implantation.

The anneal is performed to remove ion implantation damage from the substrate 122 and to activate the implanted dopant ions. Preferred annealing temperatures are between about 750° C. to 900° C. in a conventional furnace or between about 800° C. to 1000° C. in a rapid thermal anneal infra-red lamp system. After annealing, a layer of planarizing material 224 is spun or sprayed to a thickness of between about 2000-5000 Å, as shown in FIG. 6(e). This planarizing material 224 is preferably one of polyimide, SiN or Si₃N₄, but could be any other commonly used planarizing material known to those skilled in the art. The coated wafer is preferably plasma etched using CF₄/O₂, the admixture selected to equalize the etch rates of the dielectric encapsulant 222 and the planarizing layer 224 in accord with the refractive index of the dielectric 222, although other etch recipes and processes can be used. The planarizing material 224 is etched until the gate electrode 210 is sufficiently exposed (e.g., along an entire lateral expanse), as shown in FIG. 6(f).

A pair of openings 223 are then formed in the dielectric 222 above the source and drain regions, 215 and 214 respectively. Source ohmic contact S and drain ohmic contact D are then deposited into these openings by evaporation and liftoff, as shown in FIG. 6(f). The S and D ohmic contacts may comprise, for example, a mixture of gold, germanium, and nickel (AuGeNi). In one aspect of the invention, the thickness of the ohmic contacts is about 0.5 microns.

A metallization layer (not separately shown), such as Au, titanium-palladium-gold (TiPdAu), or titanium-germanium-gold (TiGeAu), is then formed to a thickness of about 0.5 microns on gate electrode 210 and patterned to form an MES gate 240 comprising gate electrode 210 and overlay metal 228, as shown in FIG. 6(g). Overlaying a TiPdAu metal layer 228 on the Schottky contact or gate electrode 210 by evaporation and liftoff dramatically reduces the gate resistance since it has both a larger cross-section area and much higher electrical conductivity than the underlying TiWN Schottky contact 210. Because the Au-based overlayer or cap 228 is insulated from the GaAs surface by the planarizing dielectric 222, the overlayer 228 alignment tolerance is not critical. In addition to reducing the FET gate resistance, this metallization layer, such as TiPdAu, also serves as a first-level metal for MMIC fabrication, e.g., as a capacitor bottom plate, as discussed in more detail below. If desired, the metallization layer (not shown) can also be formed and patterned to dispose a metallization on the drain spacing region to form a MIS gate, such as used for a MIS/MES FET. After patterning, the device is heated to a temperature between about 350° C. to 500° C. to alloy the ohmic contacts and finish the MES FET, save external connections to other circuit elements.

FIG. 6(h) shows a bumping step. This step may be performed by depositing an insulating layer 250 of silicon nitride (SiN) or other suitable dielectric on the top surface of each of the gate 240, source S, and drain D finger electrodes to extend uniformly across the entire active area. Nitride via holes 252 are then formed in the insulating layer 250 at drain D and source S fingers. A metallization layer is then desposited over the insulating layer 250 so as to fill the vias 252 and electrically couple the ohmic metal layers with a first metal layer of plated gold, or other suitable metal or metal alloy. Suitable metallization layers include, but are not limited to, Au, titanium-palladium-gold (TiPdAu), or titanium-germanium-gold (TiGeAu). Excess metallization may then be removed using conventional techniques and, optionally the dielectric subject to etch back, to expose the bumped conductive source 254 and drain 256 fingers, as shown in FIG. 6(h). These first-level metallizations are typically between about 4-5 μm thick and are preferably 4.5 μm thick in the presently described application.

FIG. 6(i) illustrates a step in the formation of second-level interconnect metallizations. A polyimide or other suitable dielectric material such as plasma-deposited SiN, SiON, or Si₃N₄ is used to form, by conventional techniques, a dielectric layer 260 for use as a dielectric crossover or bridge before the final scratch protection is applied. A typical thickness range of the scratch protection is about 3-10 microns, but a greater or lesser thickness could be utilized. The dielectric layer 260 is then planarized surface and vias 261 are formed in the dielectric layer 260 by etching through a patterned photoresist layer (not shown) to permit contact between the second-level interconnect metallization 280 and the first-level interconnect metallizations, such as but not limited to source ohmic contact S. The second-level interconnect metallization or plating 280 is deposited on a patterned etchable layer and patterned by liftoff, in one aspect, or is deposited over the dielectric layer 260 and patterned by etching in such a way that it fills the vias 261 to contact the first-level metallizations, such as source finger 254, as shown in FIG. 6(i). This second-level metallization is typically between about 2-6 microns thick and are preferably 4.5 microns thick in the presently described application. The second-level metallization 280 is used to form, for example, transmission lines, polyimide bridges, and capacitor top plates. In accord with the present invention, the second-level metallization 280 is also used, as shown, to connect the source fingers 254 of the FETs and to provide grounding to the power amplifier circuit. Additional levels of interconnection may be formed in the same way, and, if desired.

A dielectric passivation coating 290, such as polyimide, for scratch protection, is then provided as shown in FIG. 6(j). This coating 290 is applied using conventional techniques, such as sputtering and plasma-enhanced chemical vapor deposition (PECVD). The thickness of coating 290 is generally selected in accord with the invention to lie within about 4-10 μm, although other thicknesses may be selected to correspond to desired device characteristics. For example, the range of about 4-10 μm minimizes RF coupling to ground. FIG. 6(j) depicts a completed portion of an active area including source 254, drain 256, and gate fingers 240, first dielectric bridge 260, second level plating 280, and second level dielectric passivation coating 290 into which a via 290 has been opened in accord with conventional techniques to expose the FET source(s) 295.

In accord with the invention, and unlike conventional IC/RFIC/MMIC processing techniques, the wafer is flipped-over and the backside is processed as detailed in the following steps and figures to form semiconductor devices thereon such as, but not limited to, inductors and bond pads. These steps are merely examples of one way in which the backside processing may be performed. The invention disclosed herein is not dependent upon any particular processing sequences, materials, or conditions and, instead, considers only the end result of utilizing the backside of the wafer for placement of semiconductor devices, such as but not limited to passive devices including bond pads and inductors, electrically connected to a front side of the wafer bearing active components, such as but not limited to FETs or capacitors. Therefore, the invention contemplates use of any conventional processing technique(s) known to those skilled in the art or usable thereby to form the desired semiconductor devices and architecture, as disclosed herein.

In the processing step depicted in FIG. 6(k), the backside of the GaAs (or other) substrate 122 is thinned or ground back to a thickness T_{S} of about 3-5 mils. A photoresist (not shown) is then applied to the backside of the substrate 122 and exposed and removed using conventional photolithographic techniques to form a desired backside pattern with open areas (e.g., a positive photoresist) corresponding to desired via locations, as described below. Vias 300 are then selectively etched into the thinned substrate 122 using conventional well-known etchants and etching techniques suitable for etching GaAs. Such techniques include, but are not limited to wet etching, dry etching (including, e.g., Reactive Ion Etching (RIE), Reactive Ion Beam Etching (RIBE), Ion Beam Assisted Etching (IBAE)), laser drilling, punching and/or mechanical drilling, or any combination thereof.

The vias 300 are formed to extend through the front side of the substrate 122, substantially as shown. In accord with current design rules and manufacturing tolerance, it is preferred that the via 300 opening span about 50-70 μm, but other larger or smaller via sizes, such as 10-50 μm may be advantageously integrated with the invention. In general, it is preferred that the cross-section of the vias 300 be as small as possible. Following via 300 formation, a layer of metallization 310, such as gold or a gold alloy, is applied using conventional techniques, such as sputtering of PECVD, to the backside of the substrate to fill in vias 300 and uniformly coat the backside of the substrate. The preferred thickness of this metallization layer 310 is between about 3-12 μm. If the layer 310 is too thick, then the line tolerances increase. If the layer 310 is too thin, then the current carrying capability degrades. In one aspect of the invention, the metallization layer 310 comprises a multi-layer of, for example, a titanium adhesion layer of about 800 Å, a platinum or palladium layer of about 400 Å-1000 Å, and an outer gold layer of about 4000 Å or greater.

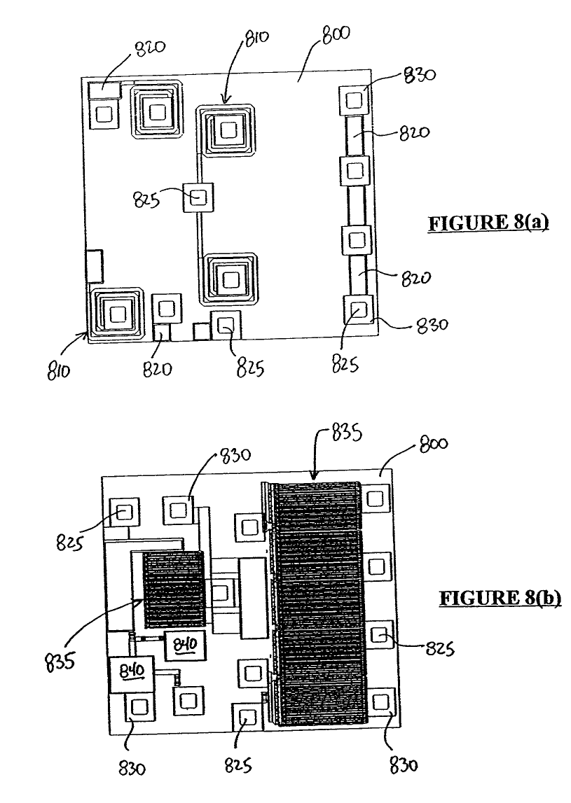

Alternatively, and as shown in accompanying FIGS. 8(a) and 8(b), discussed below, a metal plating may be patterned and applied to form metallized padding areas (see reference numeral 830 in FIG. 8(a)) to overlap, surround, or at least partially circumscribe the via 300 (shown as reference numeral 825 in FIG. 8(a)). This step is preferably performed prior to formation of the via 300, but may be performed after via formation. The metallized padding areas serve to minimize the need for high precision placement of the via 300. As can be appreciated by those skilled in the art, it is desired to minimize the necessary tolerances in this backside process. Such minimized tolerancing improves throughput and, as such, the semiconductor components selected for inclusion on the backside of substrate 122 are desirously those components, such as bond pads, inductors, etc., that do not require the utmost tolerancing. Presently, it is desired to implement a design rule of 10 micron minimum feature size and 10 micron spacing on the backside, whereas the current design rule for the active area of the front side is 6 micron minimum feature size and 6 micron spacing. It is also noted that the inventive process is compatible with both liftoff metallization and plating metallization processes, which can yield line thicknesses that differ substantially. The present invention, however, may also be implemented using the same design rules on both sides of the wafer. In other words, processing the back side of the wafer to the same spacing and tolerances demanded of the front, active side of the wafer. Accordingly, the present invention also includes within its intended scope the inclusion of design features requiring such increased precision on the back side of the wafer, including, for example, capacitors. Moreover, the present design rules are considered non-limiting as it is understood that such limitations will trend downward over time, and the present design rules and spacing merely serve as a guide for understanding the inventive aspects of the present invention.

FIGS. 6(l)-6(n) depict various steps in the formation of passive components, such as inductors and bond pads, on the backside metallization layer 310. A photoresist 320 is applied over the metallization layer 310 and desired passive components are patterned therein using conventional photolithographic techniques, as shown in FIG. 6(l). The exposed photoresist is then etched using appropriate wet or dry techniques, known to those skilled in the art, to produce the desired pattern shown in FIG. 6(m). An etchant residue removal step, including additional dry processing (e.g., ashing in a gas plasma) or wet processing (e.g., solvent) is optional. Following definition of the pattern, the photoresist 320 is stripped using well-known techniques and the remaining passive components, such as bond pads 315 and inductors 316, are coated with a passivation layer 325, such as polyimide, applied using conventional techniques, such as spin coating, sputtering or PECVD. Openings 330 are then formed in the passivation layer 325 corresponding to locations of the bond pads 315, or other designated form of electrical interconnects, to permit wire bonding to the bond pads.

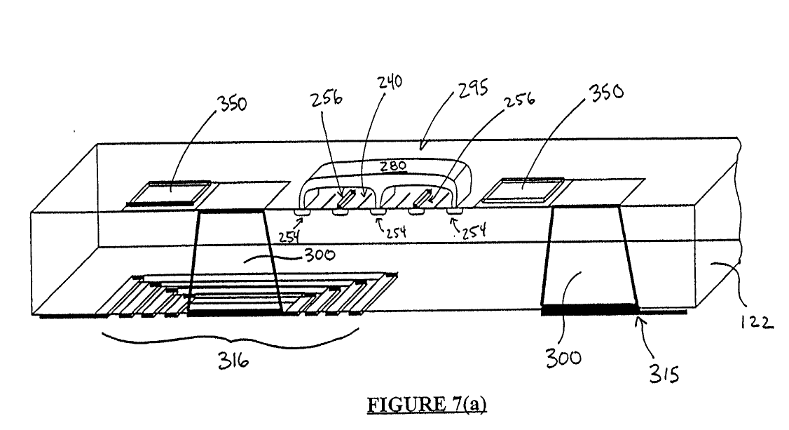

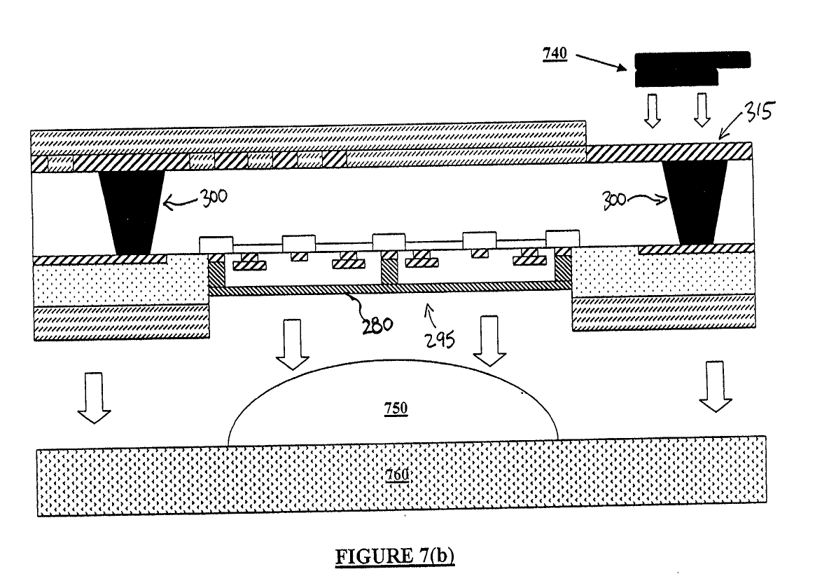

FIG. 7(a) shows a perspective, simplified view of the IC structure formed substantially in accord with the general process of steps illustrated in FIGS. 6(a)-6(n). FIG. 7(a) itself forms no intended circuit, but demonstrates the three-dimensionality of the above-described wafer processing and full utilization of all available GaAs real estate on both sides of the wafer wherein the two sides of the wafer are interconnected using backside vias. The low-level detail view of FIG. 7(a) shows two capacitors 350, two backside vias 300, a patterned inductor 316 on the backside of the wafer, and a four-gate finger FET 295 with three source fingers 254 bridged together using the second level plating gold 280. The top plates of the capacitors 350 and drain fingers 256 of the FET are formed and connected using first level plated gold, and the bottom plates of the capacitors 350 and gate fingers 240 are formed and connected using the first level metal (e.g., liftoff Ti/Pd/Au). Bond pads 315 are formed on the backside of the wafer. In other words, the bond pads 315 are on the opposite side to the four-gate finger FET 295.

FIG. 7(b) shows a simplified view of assembly of the completed wafer 700 or IC structure (e.g., a dual sided power amplifier) into a package. The wafer 700 is positioned with the active area or front side of the wafer facing down and the wafer is aligned opposite a package or carrier 760, serving as a heat sink and as a ground. The alignment is performed using conventional alignment techniques, such as registration marks. At positions corresponding to at least the exposed metallizations 280 of the FETS 295, a pre-cured epoxy 750 or other suitable conventional adhesive agent, is disposed to adhere the wafer 700 to the package 760 and to serve as an electrical and thermal conduit enabling the exposed metallization 280 on the front side of the chip to serve as the ground layer. Alternately, a solder may be use in lieu of epoxy 750. Suitable epoxies for high power applications include conventionally recognized high thermal conductivity or low thermal resistance epoxies such as, but not limited to, that manufactured by Ablebond (product number 84-1LM-SR4). This or other epoxies may be selected for low-noise, low power, or general amplification purposes. Following integration of the wafer 700 and package 760, wire bonds 740 are disposed adjacent the bond pads 315 formed on the backside of the wafer and bonded to the bond pads using conventional techniques, such as, but not limited to, ultrasonic welding.

FIGS. 8(a) and 8(b) respectively depict a back side of the die 800 and a front side or active side of the die.

As seen in FIG. 8(a), the back of die 800 includes passive elements that do not require precision manufacturing tolerances, such as inductors 810 and bond pads 820. These passive devices may be fabricated by any conventional fabrication techniques, known to those skilled in the art. Notably, the inventive placement and configuration of inductors 810 permit attainment of high current/high Q, in part since first-level metal crossovers are avoided. The Q factor of an inductor is a magnitude of the ratio of its reactance to the effective series resistance at a particular frequency and serves as an important gauge of the inductors performance since it significantly affects the frequency response of the circuit. As previously described, the bond pads 820 enable electrical communication between the devices located on the back of die 800 to vias 825. Vias 825 extend through die 800, permitting communication between devices on the front and rear of die 800.

In accord with the present invention, passive components such as inductors 810 and bond pads 820 are disposed on the opposite, underutilized portion of the die 800, to provide device integration unrealized by conventional IC wire bond and flip-chip packaging techniques. FIG. 8(b) depicts the front of die 800, on which are formed active elements requiring precision manufacturing tolerances, such as FETs 835 and capacitors 840.

In accord with the above-described configuration, additional components or chips may be affixed to and bonded to the bond pads 315 to achieve further device integration. For example, a parallel plate ceramic capacitor may be connected to the backside of wafer 700. Still further, a second, smaller wafer could be stacked on top of the first wafer and wire bonding to the bonding pads 315, providing a multi-layer configuration. Still further, a second chip could be stacked on top of the first chip and bonded, such as by a ball grid array, to the bonding pads or by using epoxy to a plated ground region on the exposed backside of the first chip, providing a multi-layer stacked chip configuration. For such multi-layer configurations, care would have to be taken relative to any inductors or bond pads 315 formed adjacent adjoining wafer surfaces to minimize potential for short circuit.

As shown in FIG. 9, for example, a second chip 900 attached to the backside of the flipped power amplifier (PA) chip 940 is placed on an attach pad 905 formed from backside metal (preferably grounded) of the PA chip. PA chip 940 itself is attached to conventional die packaging 960 by means of epoxy 970 and is electrically connected to bonding pads 915 thereon via wirebonds 910 and bond pads 925. Vias 930 are provided to enable connection between the active components, devices, or regions 950 on one side of the PA chip 940 with the passive components, such as bond pads 925, on the opposite side of the PA chip 940 in accord with the invention. Inductors 920 and bond pads 925 formed on the backside of the flipped chip 940 are spaced apart from the second smaller “face-up” chip 900 to minimize occurrence of interaction between components, such as physical contact of wirebonds 910 with other components which could lead to a short circuit. The epoxy 970 under the second chip 900, being sandwiched between the second chip and the PA chip 940, bleeds out (˜100 μm) when pressure is applied to the top chip or die 900 during an attaching step.

Although certain specific embodiments of the present invention have been disclosed, it is noted that the present invention may be embodied in other forms without departing from the spirit or essential characteristics thereof. The present embodiments are therefor to be considered in all respects as illustrative and not restrictive, the scope of the invention being indicated by the appended claims, and all changes that come within the meaning and range of equivalency of the claims are therefore intended to be embraced therein.

What is claimed is:

1. A method of manufacturing a semiconductor device, said method comprising the steps of:
(a) performing front side processing on a front side of the substrate to form an active semiconductor device on the front side of the substrate; and
(b) performing back side processing on the back side of the substrate including the steps of:
(i) forming a via through the back side of the substrate to an electrically conductive layer formed on the front side of the substrate;
(ii) forming a conductive layer in said via to form an electrically conductive path from the back side of the substrate to the electrically conductive layer formed on the front side of the substrate;
(iii) forming a passive semiconductor device on the back side of the substrate; and
(iv) forming an electrical connection between the passive semiconductor device, the via, and the electrically conductive layer formed on the front side of the substrate.

2. A method of manufacturing a semiconductor device according to claim 1, wherein said step of forming an electrical connection between the passive semiconductor device, the via,
and the electrically conductive layer formed on the front side of the substrate comprises forming an electrical connection between the active semiconductor device on the front side of the substrate and the passive semiconductor device on the back side of the substrate.

3. A method of manufacturing a semiconductor device according to claim 2, wherein said step of forming a via through said substrate is performed by using at least one of wet etching, dry etching, laser drilling, punching, or mechanical drilling processes.

4. A method of manufacturing a semiconductor device according to claim 2, wherein said step of performing front side processing on a substrate to form an active semiconductor device on a front side of said substrate comprises steps forming at least one of a transistor and a capacitor.

5. A method of manufacturing a semiconductor device according to claim 4, wherein said transistor comprises a field effect transistor.

6. A method of manufacturing a semiconductor device according to claim 4, wherein said step of forming a passive semiconductor device on a back side of said substrate comprises steps forming an inductor.

7. A method of manufacturing a semiconductor device according to claim 4, wherein said step of forming a passive semiconductor device on a back side of said substrate comprises steps forming at least one bond pad.

8. A method of manufacturing a semiconductor device according to claim 7, further comprising the steps of:
(c) attaching a semiconductor device to the backside of the substrate; and
(d) electrically connecting said semiconductor device to said at least one bond pad.

9. A method of manufacturing a semiconductor device according to claim 8, wherein said semiconductor device is a semiconductor chip.

10. A method of manufacturing a semiconductor device according to claim 8, wherein said semiconductor device is an active semiconductor device.

11. A method of manufacturing a semiconductor device according to claim 8, wherein said semiconductor device is a passive semiconductor device.

12. A method of manufacturing a power amplifier, comprising the steps of:
(a) forming an active semiconductor device comprising a field effect transistor on one side of a substrate;
(b) forming a via through the substrate;
(c) filling the via with an electrically conductive material;
(d) forming a passive semiconductor device comprising at least one of an inductor and a bond pad on another side of the substrate opposing said one side; and
(e) electrically connecting the passive semiconductor device to the active semiconductor device through the via.

13. A method of manufacturing a semiconductor device according to claim 8, wherein said step of forming an active semiconductor device comprising a transistor on one side of a substrate comprises steps forming a field effect transistor.

14. An integrated circuit comprising, in combination:
a substrate having a front side and a back side;
an active device disposed on the front side of the substrate;
a passive device disposed on the front side of the substrate;
a via bearing a conductive material extending from the back side of the substrate to the front side of the substrate; and
electrical connectors connecting a respective one of the active device and passive device to the via conductive material to form an electrical connection between the active device on the front side of the substrate and the passive device on the back side of the substrate.

15. An integrated circuit according to claim 14, wherein said active device is at least one of a field effect transistor and a capacitor.

16. An integrated circuit according to claim 15, wherein said passive device is at least one of an inductor and a bond pad.

17. An integrated circuit according to claim 16, wherein said substrate is a GaAs substrate.

18. An integrated circuit according to claim 16, further comprising at least one of a semiconductor chip and a semiconductor active device or passive device disposed on the back side of the substrate.

19. An integrated circuit according to claim 16, wherein said integrated circuit comprises a power amplifier.

20. An integrated circuit according to claim 16, wherein said integrated circuit comprises a monolithic microwave integrated circuit (MMIC).
